(19) United States
(12) Patent Application Publication
(10) Pub. No.: US 2011/0117706 A1
(43) Pub. Date: May 19, 2011

(54) PROTECTIVE TAPE JOINING METHOD AND PROTECTIVE TAPE JOINING APPARATUS

(76) Inventors: Akinori Nishio, Osaka (JP); Kazuyuki Kiuchi, Osaka (JP); Masayuki Yamamoto, Osaka (JP); Naoki Ishii, Mie-ken (JP)

(21) Appl. No.: 13/000,395

(22) PCT Filed: Oct. 9, 2009
(86) PCT No.: PCT/JP2009/005278

§ 371 Date: Dec. 21, 2010

(30) Foreign Application Priority Data
Oct. 16, 2008 (JP) 2008-267723 2008

(51) Int. Cl. H01L 21/56; B29C 65/56

(52) U.S. Cl. 438/127; 156/498; 257/E21.502

(57) ABSTRACT

A cooling plate having a cooling pipe mounted therein in a serpentine shape is placed in a stack manner on a rear face of a chuck table for suction-holding a rear face of the semiconductor wafer. A coolant is circulated through the cooling pipe, thereby cooling the chuck table. The semiconductor wafer is suction-held while the chuck table is cooled. In addition, the protective tape is joined to the semiconductor wafer while the chuck table is cooled. That is, the protective tape is joined to the surface of the semiconductor wafer while being cooled indirectly via the semiconductor wafer cooled in advance through direct contact to the chuck table during joining of the protective tape.

### TECHNICAL FIELD

This invention relates to a method and apparatus for joining a protective tape to a surface of a semiconductor wafer having a circuit pattern formed thereon.

### BACKGROUND ART

A semiconductor wafer (hereinafter, simply referred to as a “wafer”) has a surface having a circuit pattern formed thereon. A rear face of the wafer is ground and thinned in a back grinding process. Subsequently, the wafer is divided into every chip in a dicing process. The wafer tends to be thinned to have a thickness of 100 μm to 50 μm or even less in recent years with a need for a high-density package.

The wafer has a protective tape joined to the surface thereof upon thinning of the wafer in the back grinding process. This is performed in order to protect the surface of the wafer having the circuit pattern formed thereon, and to protect the wafer from a grinding stress in the back grinding process.

For instance, a method of joining a protective tape to a surface of a wafer is implemented as follows. A band-shaped protective tape having an adhesive face directed downward is supplied above a semiconductor wafer that is suction-held by a chuck table. A joining roller then rolls on the surface of the protective tape, thereby joining the protective tape to the surface of the wafer. Subsequently, a cutter blade of a tape cutting device pierces the protective tape and moves along an outer periphery of the wafer, allowing the joined protective tape to be cut along a contour of the wafer. An unnecessary portion of the tape cut out along the contour of the wafer is wound and collected (see Patent Literature 1.)

### Patent Literature 1

Japanese Patent Publication No. 2005-116711

### DISCLOSURE OF THE INVENTION

### Problem to be Solved by the Invention

The wafer having a surface with the protective tape joined thereto that is subjected to the back grinding process to be of a given thickness is likely to bend inwardly. For instance, the wafer is affected by a warp that occurs under the influence of stress accumulated through elastic deformation and extension of the protective tape upon pressing and rolling of the joining roller. In addition, where the wafer has a resin film, such as polyimide, on the surface thereof, such a warp occurs as the surface of the wafer bends inwardly due to thermal shrinkage of the resin film under the influence of the heat generated in the back grinding process.

The wafer with the protective tape that is subjected to the back grinding process is suction-held from either of front and rear face sides of the wafer upon transportation to various subsequent processes and handlings during the processes. Accordingly, where the wafer bends inwardly and greatly, there arises a problem that a handling error occurs due to poor suction of the wafer.

This invention has been made regarding the state of the art noted above, and its primary object is to provide a protective tape joining method and protective tape joining apparatus that allows suppressing of a warp occurs in a semiconductor wafer that is subjected to a back grinding process.

### Means for Solving the Problem

This invention is constituted as stated below to achieve the above object. This invention relates to a method of joining a protective tape to a surface of a semiconductor wafer having a circuit pattern formed thereon, in which the protective tape is joined to the surface of the semiconductor wafer at a temperature lower than ordinary temperatures.

(Effect) According to the method, the protective tape is joined to the surface of the wafer while being cooled at a temperature lower than ordinary temperatures and thermally shrunk in advance. Subsequently, restoring force for returning to its original shape with thermal expansion from heating or ordinary temperatures acts on the protective tape that is thermally shrunk in advance due to influence of heat through friction in the back grinding process or releasing to ordinary temperatures. That is, a warp acts on the wafer that is of an opposite direction to the warp that the surface of the wafer is likely to bend inwardly after the back grinding process through thermal expansion or restoring force of the protective tape. Consequently, stress that generates the warp after the back grinding process is offset by stress that newly occurs with the protective tape. As a result, the warp of the wafer may be suppressed.

In the foregoing embodiment, a chuck table that holds the foregoing semiconductor wafer is cooled, and the protective tape is cooled via the cooled semiconductor wafer.

(Effect) According to the method, the semiconductor wafer functions as a thermal diffusion plate. The protective tape is joined to the surface of the semiconductor wafer uniformly while being cooled.

In the foregoing invention, the protective tape is joined to the semiconductor wafer while cooled gases are blown to the protective tape.

In the foregoing invention, the band-shaped protective tape is joined to the semiconductor wafer while being fed out from an original master roll that is housed in an insulating container.

(Effect) According to the foregoing methods, the protective tape may positively be cooled prior to joining thereof to the semiconductor wafer, and the protective tape shrunk in advance may be joined to the semiconductor wafer.

This invention also adopts the configuration as stated below to accomplish such object.

This invention discloses protective tape joining apparatus for joining a protective tape to a surface of a semiconductor wafer having a circuit pattern formed thereon. The apparatus includes a holding table that holds the semiconductor wafer; a tape supplying device that supplies the protective tape above the surface of the semiconductor wafer held by the holding table; a tape joining device that joins the supplied protective tape to the surface of the semiconductor wafer while pressing and rolling a joining roller; a tape cutting device that cuts the joined protective tape along an outer periphery of the semiconductor wafer; an unnecessary tape collecting device that collects an unnecessary portion after cut out; and a tape cooling device that cools the protective tape to be joined to the surface of the semiconductor wafer.

(Effect) With the configuration, the protective tape is positively cooled and joined to the surface of the semiconductor wafer while being shrunk in advance. That is, suitable implementation of the foregoing invention may realize joining of the protective tape to the surface of the semiconductor wafer.

In the foregoing configuration, the tape cooling device cools, for example, the chuck table.

(Effect) With the configuration, the protective tape is joined to the cooled semiconductor wafer via the joining roller, and accordingly, the protective tape is indirectly cooled sequentially from a joined portion thereof. Consequently, the protective tape is to be entirely joined to the surface of the wafer W with being cooled uniformly.

For instance, in the foregoing configuration, the tape cooling device circulates a coolant through a circulation pipe provided in the holding table.

(Effect) With the configuration, the coolant is controlled in temperature or flow rate, whereby the chuck table may be cooled to any temperature. Consequently, suitable cooling may be performed in easy response to variations in types of the semiconductor wafer and the protective tape.

In the foregoing configuration, the foregoing tape cooling device is a Peltier device, for instance, that is mounted in the foregoing holding table.

(Effect) With the configuration, the chuck table may be cooled to any temperature through control of passage of current through the Peltier devices. Moreover, suitable cooling may be performed in easy response to variations in types of the semiconductor wafer and the protective tape. Furthermore, a problem on leakage is not in need of consideration compared with the case where a coolant is used. Consequently, easy operation management may be realized using this apparatus.

In the foregoing configuration, the tape cooling device is a nozzle, for example, for blowing cooled gasses.

(Effect) With the configuration, the cooled gases may be directly supplied to the protective tape that is supplied on the table to rapidly cool the protective tape while the chuck table is cooled.

### EFFECT OF THE INVENTION

As noted above, according to the protective tape joining method and the protective tape joining apparatus of this invention, the protective tape is cooled and joined to the surface of the semiconductor wafer while being shrunk in advance. Consequently, the warp of the wafer having the protective tape subjected to the back grinding process may be suppressed to be a slight one. As a result, occurrence of handling errors may be eliminated upon transportation of the wafer in various processes subsequent to the back grinding process.

### BRIEF DESCRIPTION OF THE DRAWINGS

FIG. 1 is a perspective view showing a whole configuration of a protective tape joining apparatus.

FIG. 2 is a plan view of a chuck table.

FIG. 3 is a front view of a principal portion including the chuck table.

FIGS. 4 to 7 are front views each showing a step of joining a protective tape.

FIG. 8 is a plan view of a chuck table according to another embodiment.

FIG. 9 is a front view of a principal portion including the chuck table according to another embodiment.

FIG. 10 is a plan view of a chuck table according to another embodiment.

FIG. 11 is a front view of the chuck table according to another embodiment.

### DESCRIPTION OF REFERENCES

5 . . . chuck table
22 . . . cooling plate
23 . . . cooling pipe
24 . . . cooling device
25 . . . circulation pump
26 . . . Peltier device
27 . . . air source
28 . . . nozzle
T . . . protective tape
W . . . semiconductor wafer

### BEST MODE FOR CARRYING OUT THE INVENTION

One exemplary embodiment of this invention will be described in detail hereinafter with reference to the drawings.

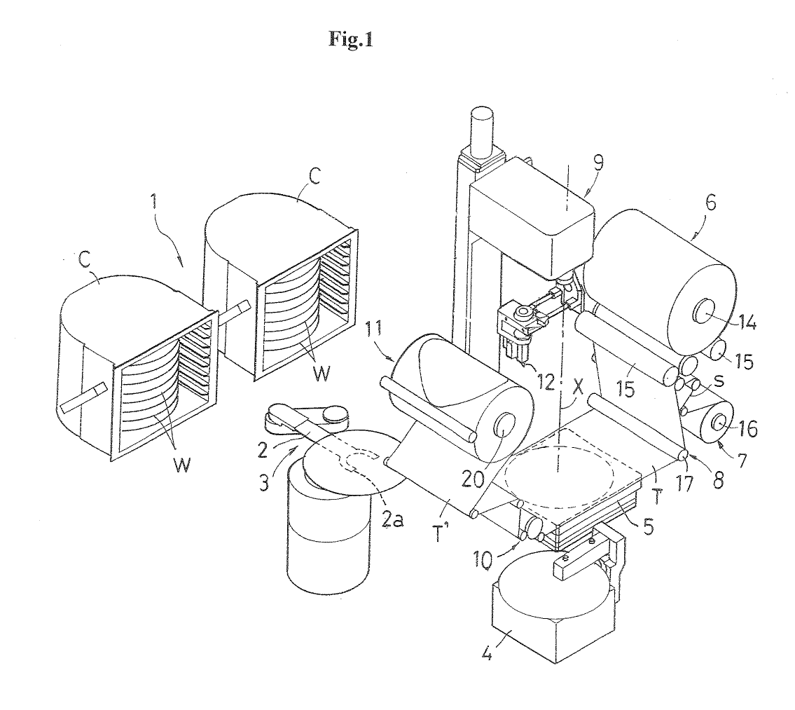

FIG. 1 is a perspective view showing a whole configuration of a protective tape joining apparatus.

The protective tape joining apparatus includes: a wafer supply/collection section 1 with a cassette C mounted therein that houses a semiconductor wafer (hereinafter, simply referred to as a “wafer”) W; a wafer transport mechanism 3 with a robot arm 2; an alignment stage 4; a chuck table 5 that suction-holds the wafer W placed thereon; a tape supply section 6 that supplies a protective tape T above the wafer W; a separator collection section 7 that separates, from the protective tape T with a separator s that is supplied from the tape supply section 6, the separator s and collects the separator s; a joining unit 8 that joins the protective tape T to the wafer W placed on and suction-held by the chuck table 5; a tape cutting device 9 that cuts out the protective tape T joined to the wafer W along a contour of the wafer W; a separation unit 10 that separates an unnecessary tape T′ produced after joining to the wafer W and cutting out; a tape collection section 11 that winds and collects the unnecessary tape T′ separated by the separation unit 10; and others. Hereinafter, description will be given to a detailed configuration of each component and mechanism.

The wafer supply/collection section 1 has two cassettes C mounted therein arranged in parallel. Many wafers W are inserted into and housed in each cassette C in a stack manner in a state where each wafer W is housed in a horizontal attitude with a wiring pattern face (a surface) thereof being directed upward.

The robot arm 2 of the wafer transport mechanism 3 may move forward and backward horizontally. Moreover, the entire robot arm 2 is driven to turn and move liftably. The robot arm 2 has at the tip end thereof a wafer holder 2a of a vacuum suction type formed in a horseshoe shape. That is, the wafer transport mechanism 3 inserts the wafer holder 2a between the stacked wafers W housed in the cassette C, and suction-holds a rear face of the wafer W. The robot arm 2 pulls out the suction-held wafer W from the cassette C, and transports the wafer W to the alignment stage 4, the chuck table 5, and the wafer supply/collection part 1 in turn.

The alignment stage 4 performs alignment on the wafer W that is transported and placed thereon by the wafer transport mechanism 3, based on a notch or an orientation flat formed at an outer periphery of the wafer W.

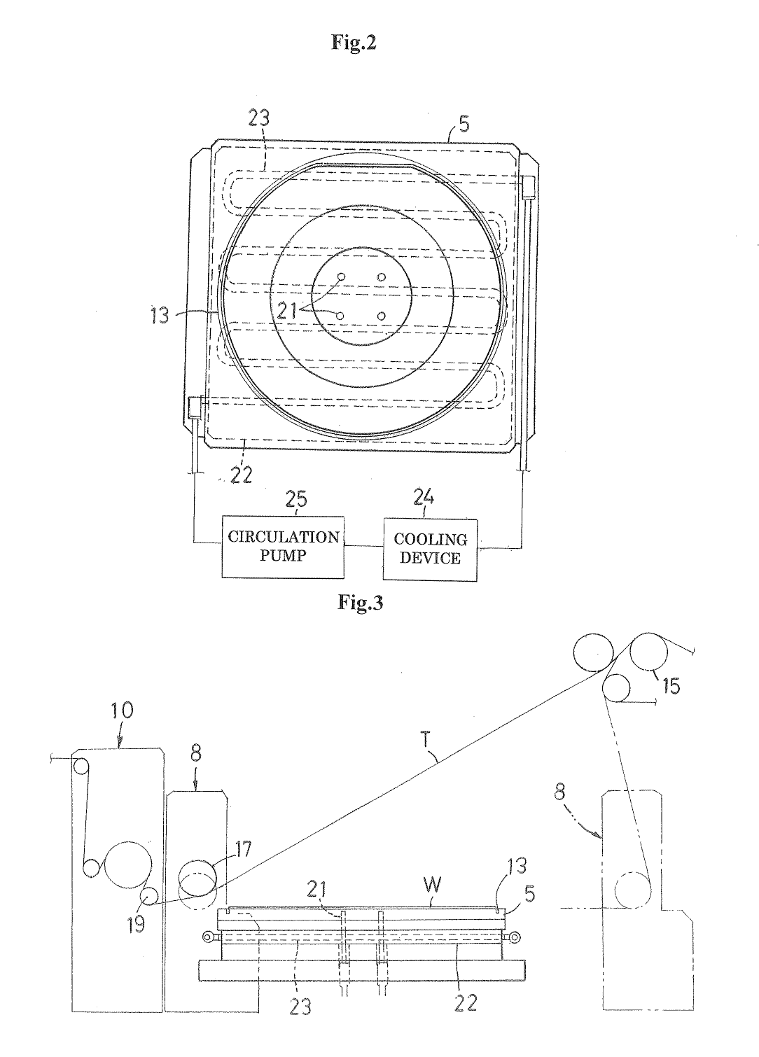

As shown in FIGS. 2 and 3, the chuck table 5 has a cutter traveling groove 13 annularly formed on the surface thereof. The chuck table 5 also has two or more (four in this embodiment) wafer support pins 21 placed at a center thereof such that the pins may move in and out therefrom. The holding table has a cooling plate 22 formed on the rear face thereof in a stack manner. The cooling plate 22 has a cooling pipe 23 loaded inside thereof in a serpentine shape. The coolant (cooling fluid or coolant gas) cooled with the cooling device 24 circulates through a circulation pump 25, thereby cooling the chuck table 5. The wafer support pins 21 in the chuck table 5 are arranged so as to avoid a position of the cooling pipe 23 and support the wafer W in equal weight distribution.

The cooling plate 22, the cooling device 24, and the circulation pump 25 constitute the tape cooling device of this invention.

Now referring again to FIG. 1, the tape supply section 6 has a configuration in which a protective tape T with the separator s is fed out from a supply bobbin 14, then is guided to and wound around a group of guide rollers 15, and a protective tape T with the separator s separated therefrom is guided toward the joining unit 8. Herein, the supply bobbin 14 is applied with appropriate resistance against its rotation in order to prevent the tape from being fed out excessively.

The separator collecting section 7 has a configuration in which a collecting bobbin 16 that winds the separator s separated from the protective tape T rotates in a winding direction.

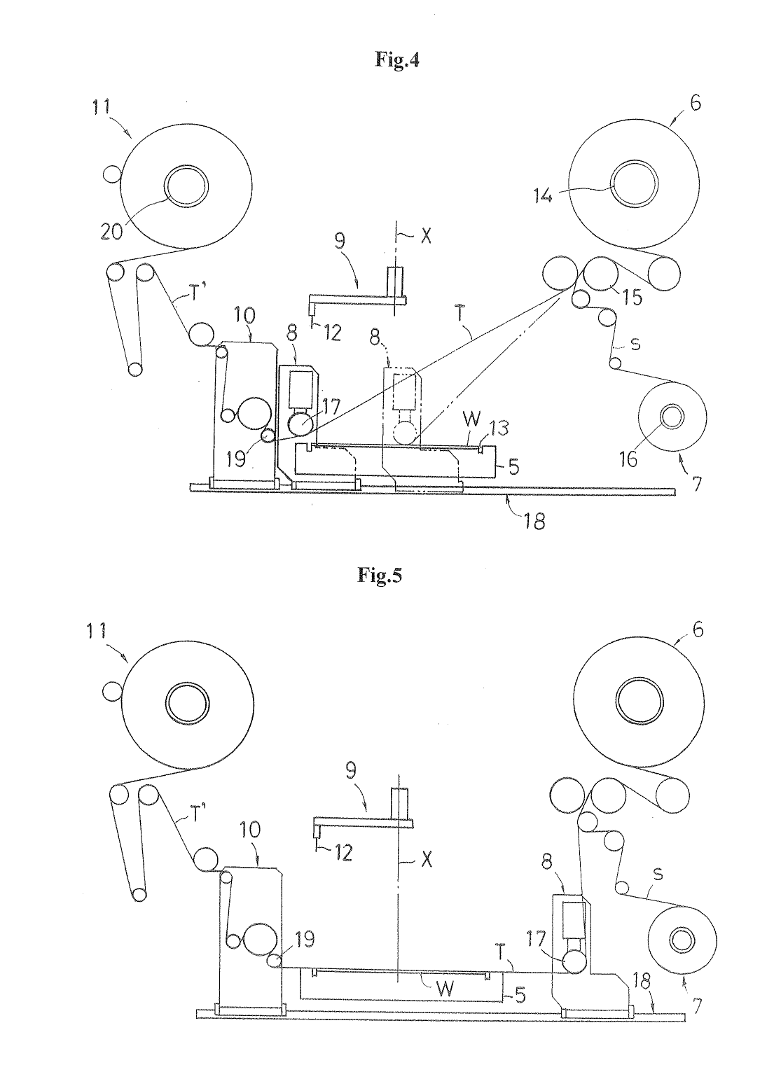

As shown in FIG. 4, a joining roller 17 is provided in the joining unit 8 so as to reciprocate horizontally with a slide guide mechanism 18 and a screw-feed type drive mechanism (not shown.)

Moreover, a separation roller 19 is provided horizontally in the separation unit 10 so as to reciprocates horizontally with the slide guide mechanism 18 and the screw-feed type drive mechanism (not shown.)

The tape collecting section 11 has a configuration in which a collecting bobbin 20 that winds the unnecessary tape T′ rotates in a winding direction.

The tape cutting device 9 has a configuration in which a cutter blade 12 having an edge directed downward may move vertically and pivotally about a vertical axis X that passes the center of the chuck table 5.

Next, with reference to FIGS. 4 to 7, description will be made of a series of operations for joining the protective tape T to the surface of the wafer W and then cutting the protective tape T using the foregoing exemplary embodiment of this invention.

A joining command is issued, and then the robot arm 2 moves towards the cassette C placed on the cassette table 12. The wafer holder 2a is inserted between the wafers housed in the cassette C, and suction-holds the rear face (underside) of the wafer W for transportation. The robot arm 2 moves and places the pulled-out wafer W to the alignment stage 4.

The alignment stage 4 performs alignment of the wafer W placed thereon, through use of a notch formed at the outer periphery of the wafer W. The robot arm 2 then transfers the aligned wafer W toward to the chuck table 5, and places the wafer W on the chuck table 5.

The wafer W placed on the chuck table 5 is suction-held so as to be aligned with the chuck table 5. Here, as shown in FIG. 4, the joining unit 8 and the separation unit 10 are on standby in an original position on the left side. The cutter blade 12 of the tape cutting mechanism 9 are on standby in an original position on the upper side.

Next, as shown in FIG. 4, the joining roller 17 of the joining unit 8 moves downward, and presses the protective tape T downward while rolling on the wafer W in the forward direction (in the right direction in plane of FIG. 4). Thus, the protective tape T may be joined to the entire surface of the wafer W and a portion out of the wafer on the chuck table 5.

Here, the cooled medium circulates through the cooling pipe 23, thereby previously cooling the wafer W that is placed on the chuck table 5 cooled in advance. Thereafter, the protective tape T starts to be joined to the wafer W, and simultaneously is cooled via the wafer W. That is, the protective tape T is joined to the surface of the wafer W while being cooled in advance at a temperature lower than ordinary temperatures and thermally shrunk.

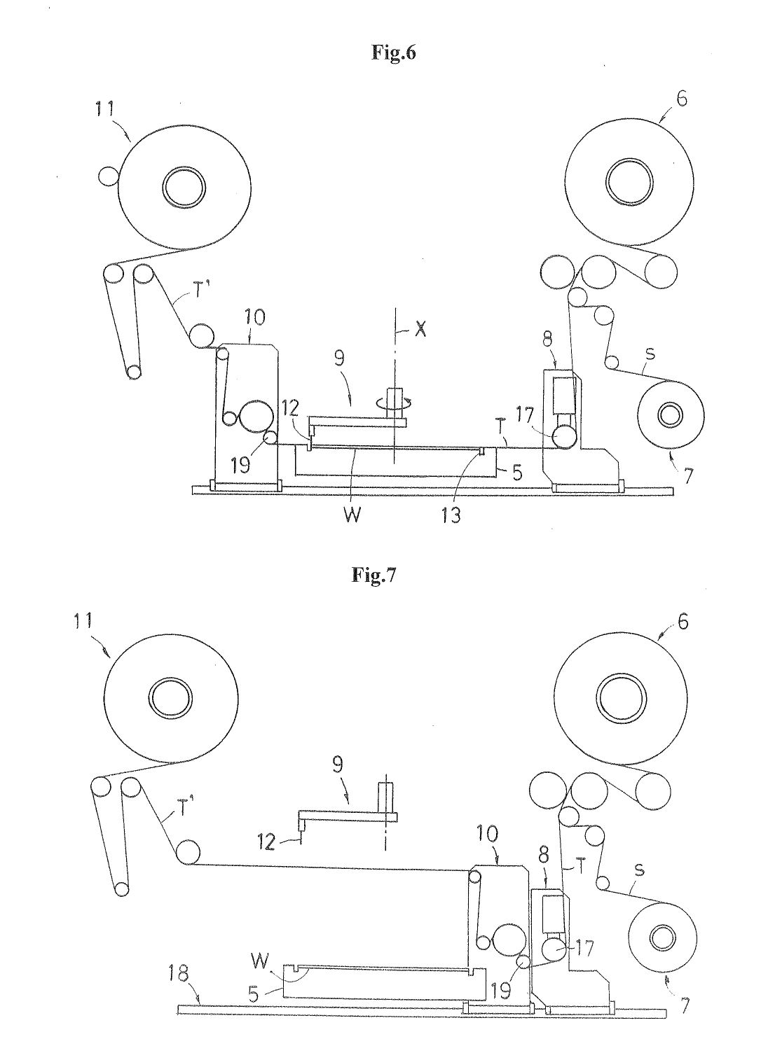

As shown in FIG. 5, when the joining unit 8 reaches a joining termination position, the cutter blade 12 on standby on the upper side moves downward. Here as shown in FIG. 6, the cutter blade 12 pierces the protective tape T on the cutter traveling groove 13 of the chuck table 5.

Next, the cutter blade 12 turns in sliding contact with the outer peripheral edge of the wafer, thereby cutting the protective tape T into a shape of the wafer.

Upon completion of cutting of the protective tape T, the cutter blade 12 moves upward to the original standby position, as shown in FIG. 7. The separating unit 10 then moves forward while lifting up and separating the unnecessary tape T′ joined around the wafer W on the chuck table 5 after cutting out in the shape of the wafer W.

When the separating unit 10 reaches a position where separating is completed, the separation unit 10 and the joining unit 8 move backward and return to its original position. Here, the collecting bobbin 20 winds up the unnecessary tape T, and the tape supplying section 6 feeds out a given amount of the protective tape T.

Upon completion of the forgoing joining process of the protective tape T, the chuck table 5 releases the suction holding of the wafer W. Simultaneously, the wafer holder 2a of the robot arm 2 transfers the wafer W subjected to the tape joining process to insert the wafer W into the cassette C in the wafer supply/collection section 1.

Thus, one tape joining process is completed as described above. Thereafter, the foregoing joining process is performed for transportation of a new wafer W.

This invention is not limited to the embodiment hereinabove, but may be modified as follows.

(1) A heat sink for heat dissipation may be joined to the rear face of the chuck table 5. Various gases, such as cooled air, may be blown to the heat sink via a nozzle for cooling. Here, the heat sink is composed of aluminum, copper, etc., and the shape thereof is variable appropriately depending on heat dissipation efficiency. The heat sink corresponds to the tape cooling device of this invention.

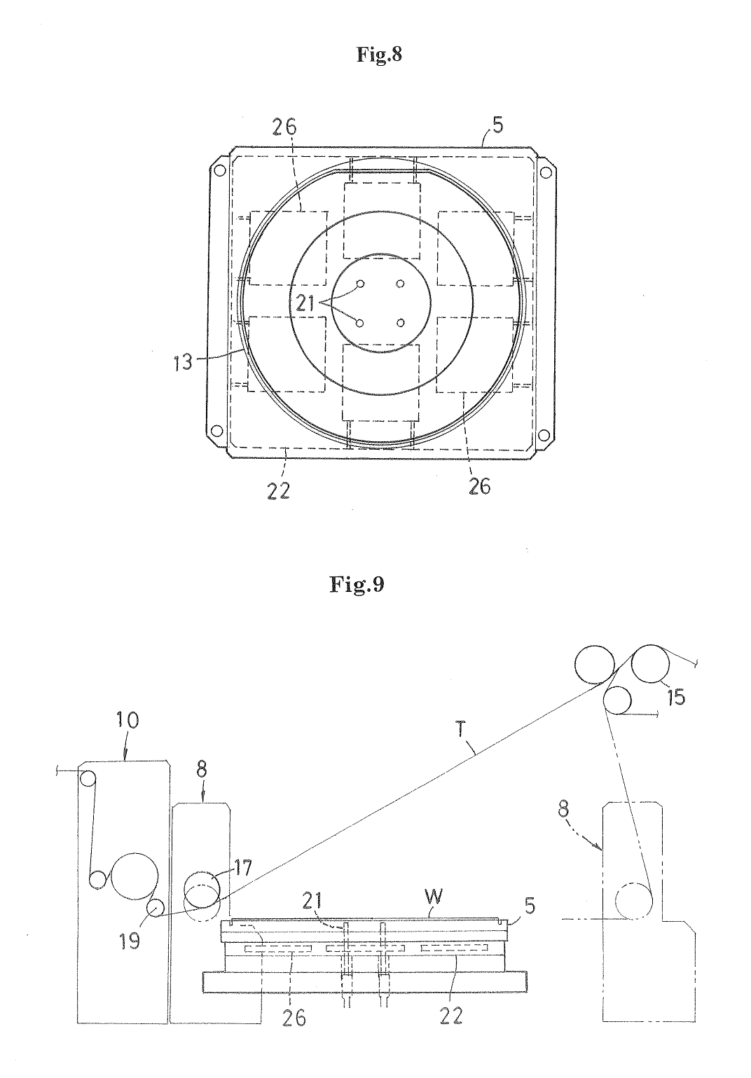

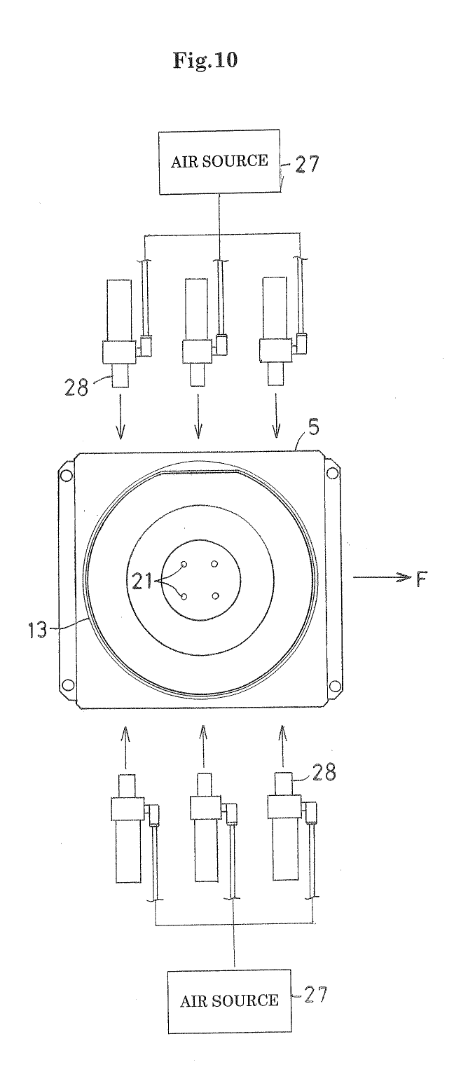

(2) As shown in FIGS. 8 and 9, the cooling plate 22 may have two or more Peltier devices 26 mounted therein for cooling the chuck table 5. Also in this configuration, cooled air from the nozzle may be blown to the Peltier devices 26, which enhances a cooling effect. Here, the Peltier device 26 corresponds to the tape cooling device of this invention.

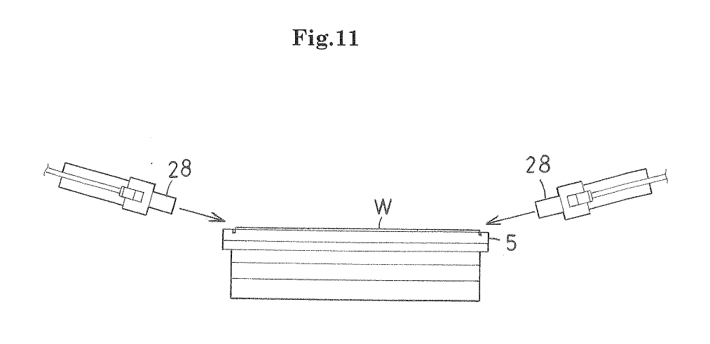

(3) As shown in FIGS. 10 and 11, nozzles 28 each in communication with an air source 27 may be arranged on both sides of the chuck table 5 that are perpendicular to a tape joining direction F for cooling the chuck table 5 and the protective tape T to be supplied through blowing of cooled gases from the nozzles 28. Therefore, the protective tape T to be joined may be cooled through direct blowing of gases, and thus the protective tape T may be controlled in temperature depending on types of protective tapes T or joining environment thereof. Here, the air source 27 and the nozzle 28 constitutes the tape cooling device of this invention.

(4) Although not illustrated, the tape supply unit 6 may be housed in a cooling room corresponding to the insulating container of this invention for cooling in advance the protective tape T to be supplied on the chuck table 5. Moreover, the tape supply unit 6 may be provided in a cooling room through which the protective tape T passes during supply thereof. That is, the protective tape T may be cooled in advance and be supplied to a joining position. Usage of each foregoing exemplary apparatus may be realized through housing of the tape supply unit 6 entirely into the cooling room and formation of a slit in the cooling room for feeding out the protective tape T.

Next, experiments for joining two or more types of protective tapes were conducted using the foregoing exemplary apparatus, apparatus with the heat sink of Modification (1) and the cooling nozzles, and apparatus with the Peltier devices of Modification (2) and the cooling nozzles. Here, each of the protective tape joining apparatus for the experiments includes the tape cooling device of the foregoing exemplary apparatus on the chuck table based on DR3000II by NITTO SEIKI Co., Ltd.

When the tape cooling device in each apparatus operated to determine in advance a temperature of the chuck table, the following results were obtained. The exemplary apparatus was allowed for setting a temperature lower by 30 degrees C. than an ordinary temperature (room temperature of 17 degrees C.) The modification apparatus (1) was allowed for setting a temperature lower by 10 degrees C. than the ordinary temperature. The modification apparatus (2) was allowed for setting a temperature lower by 50 degrees C. than the ordinary temperature.

The following four types of protective tapes were joined to a wafer having a diameter of 200 mm for the experiments.

A protective tape A was used of UB3102D by NITTO DENKO CORPORATION having a tape total thickness of 100 μm manufactured by applying an acrylic adhesive to a PET (poly-ethylene terephthalate) base material.

A protective tape B was used of UB3102 D-XX by NITTO DENKO CORPORATION having a tape total thickness of 140 μm manufactured by applying an acrylic adhesive to a PET base material of a bonded product that was made by joining the PET base material and a PET-PBT (poly-ethylene terephthalate-polybutylene terephthalate) copolymer base material via a polyester adhesive.

A protective tape C was used of UB2130E by NITTO DENKO CORPORATION having a tape total thickness of 130 μm manufactured by applying an acrylic adhesive to an ethylene-vinyl acetate copolymer base material.

A protective tape D was used of UB9180D-G15-X1 by NITTO DENKO CORPORATION having a tape total thickness of 180 μm manufactured by applying an acrylic adhesive to a polypropylene ethylene copolymer base material.

In each apparatus, upon joining of the protective tapes A to D on a surface of a silicone mirror wafer of 8 inch, comparative experiments other than that of cooling the chuck table were conducted in which no chuck table was cooled. Moreover, subsequent to joining of each protective tape, a wafer having a thickness of 725 μm prior to grinding was ground by 25 μm or 50 μm using a wafer grinder DFG8560 by DISCO Corporation.

The wafer was pulled out after the grinding process, and placed on a surface plate such that a protective tape joining surface thereof may be directed upward. Then, a portion was determined in height where the wafer has the maximum warp from a surface of the surface plate. The test results were given as an amount of warping. The experimental results were as in the following table.

TABLE 1

| | GRINDING | AMOUNT OF WARP (mm) | | | |
|---|---|---|---|---|---|
| | THICKNESS | | EXEMPLARY | MODIFICATION | MODIFICATION |
| | (μm) | NO COOLING | APPARATUS | APPARATUS (1) | APPARATUS (2) |
| PROTECTIVE | 25 | 5 | 0.5 | 0.5 | 0.5 |
| TAPE A | | | | | |
| PROTECTIVE | 25 | 15.5 | 3.3 | 3.4 | 3.5 |
| TAPE B | | | | | |
| PROTECTIVE | 50 | 8.2 | 5.4 | 5.5 | 5.6 |
| TAPE C | | | | | |
| PROTECTIVE | 25 | 32 | 16.5 | 17 | 16 |
| TAPE D | | | | | |

Where the protective tape is indirectly cooled via the chuck table, it was confirmed that the protective tape A was improved in amount of warping by approximately 90%, the protective tape B by approximately 78%, the protective tape C by approximately 32%, and the protective tape D by approximately 48%, respectively, comparing with the case where no protective tape is cooled.

Therefore, the wafer may be transported while any of the front and rear faces thereof are suction-held with almost no warp after the back grinding process, which results in no handling error.

### INDUSTRIAL UTILITY

As described above, this invention is suitable for joining a protective tape to a surface of a semiconductor wafer.

1. A method of joining a protective tape to a surface of a semiconductor wafer having a circuit pattern formed thereon, the protective tape being joined to the surface of the semiconductor wafer at a temperature lower than ordinary temperatures.

2. The method of joining the protective tape according to claim 1, wherein
a chuck table that holds the semiconductor wafer is cooled, and the protective tape is cooled via the cooled semiconductor wafer.

3. The method of joining the protective tape according to claim 1, wherein
the protective tape is joined to the semiconductor wafer while cooled gases are blown to the protective tape.

4. The method of joining the protective tape according to claim 1, wherein
the protective tape in a band shape is joined to the semiconductor wafer while being fed out from an original master roll that is housed in an insulating container.

5. Protective tape joining apparatus for joining a protective tape to a surface of a semiconductor wafer having a circuit pattern formed thereon, comprising:
a holding, table that holds the semiconductor wafer;
a tape supplying device that supplies the protective tape above the surface of the semiconductor wafer held by the holding table;
a tape joining device that joins the supplied protective tape to the surface of the semiconductor wafer while pressing and rolling a joining roller;
a tape cutting device that cuts the joined protective tape along an outer periphery of the semiconductor wafer;
an unnecessary tape collecting device that collects an unnecessary portion after cut out; and
a tape cooling, device that cools the protective tape to be joined to the surface of the semiconductor wafer.

6. The apparatus for joining the protective tape according to claim 5, wherein
the tape cooling device cools the chuck table.

7. The apparatus for joining the protective tape according to claim 6, wherein
the tape cooling device circulates a coolant, through a circulation pipe provided in the holding table.

8. The apparatus for joining the protective tape according to claim 6, wherein
the tape cooling, device is a Peltier device that is mourned in the holding table.

9. The apparatus for joining the protective tape according to claim 6 wherein
the tape cooling device is a nozzle for blowing cooled gasses.

10. The apparatus for joining the protective tape according to claim 5, wherein
the tape cooling device is a nozzle for blowing cooled gasses to the protective tape.

11. The apparatus for joining the protective tape according to claim 5, wherein
the tape cooling device is a nozzle for blowing cooled gasses to the protective tape and the chuck table.

12. The apparatus for joining the protective tape according to claim 5, wherein
the tape cooling device is an insulating container into which an original master roll is housed having the protective tape in a band shape roiled in the tape supply device.

13. The method of joining the protective tape according to claim 2, wherein
the protective tape is joined to the semiconductor wafer while cooled gases are blown to the protective tape.
